(19) United States
(12) Patent Application Publication
(10) Pub. No.: US 2025/0277813 A1
(43) Pub. Date: Sep. 4, 2025

(54) ELECTRICAL CONNECTION APPARATUS

(71) Applicant: Kabushiki Kaisha Nihon Micronics, Tokyo (JP)

(72) Inventors: Souichi KANOSUE, Oita (JP); Masataka KIMOTO, Oita (JP); Toshihisa KADOWAKI, Oita (JP); Shin SAKIYAMA, Oita (JP)

(21) Appl. No.: 19/059,116

(22) Filed: Feb. 20, 2025

(30) Foreign Application Priority Data
Feb. 29, 2024 (JP) 2024-029921

(51) Int. Cl. G01R 1/073; H05K 1/02

(52) U.S. Cl. CPC G01R 1/07314; H05K 1/028

(57) ABSTRACT

An electrical connection apparatus includes: a probe; a probe head holding the probe; a wiring sheet with flexibility including a first connection portion arranged on a first sheet surface facing the probe head and a second connection portion arranged on a second sheet surface; and a wiring board which is arranged facing the probe head with the wiring sheet therebetween and has a first electrode facing the second connection portion. The wiring sheet include: a first layer through which the first connection portion passes; a wiring layer which includes an electrode pad arranged facing the first connection portion and an internal circuit electrically connected to the electrode pad; and a second layer through which the second connection portion passes. The first layer is elastically deformed such that the first connection portion, which has received a pressing force from the probe, comes into contact with the electrode pad.

### CROSS-REFERENCE TO RELATED APPLICATIONS

The present application is based on, and claims priority from Japanese Patent Application No. 2024-029921, filed on Feb. 29, 2024, the entire contents of which are incorporated herein by reference.

### TECHNICAL FIELD

The present disclosure relates to an electrical connection apparatus used for inspecting electrical characteristics of an object to be inspected.

### BACKGROUND ART

An electrical connection apparatus having a probe is used to inspect electrical characteristics of an object to be inspected such as a semiconductor integrated circuit in a wafer state. In the inspection using the probe, one end of the probe contacts an electrode of the object to be inspected, and the other end of the probe contacts a terminal arranged on a wiring board in the electrical connection apparatus. The terminal arranged on the wiring board is electrically connected to an inspection device such as a tester.

### CITATION LIST

### Patent Literature

[Patent Literature 1] JP 2019-178901 A

### SUMMARY

In order to accurately inspect the electrical characteristics of the object to be inspected, it is necessary to stably connect the probe to the object to be inspected. Therefore, it is necessary to press the probe against the wiring board. This applies a load to the probe. However, the probe has the load endurance limit. Therefore, an object of the present disclosure is to provide an electrical connection apparatus which enables reduction of a load applied to a probe.

An electrical connection apparatus according to one aspect of the present disclosure includes: a probe; a probe head holding the probe; a wiring sheet with flexibility including a first connection portion arranged on a first sheet surface facing the probe head and a second connection portion arranged on a second sheet surface; and a wiring board which is arranged facing the probe head with the wiring sheet therebetween and on which a first electrode facing the second connection portion is arranged. The wiring sheet includes: a first layer through which the first connection portion passes; a wiring layer which includes an electrode pad arranged on a first connection surface separated from the first layer so as to face the first connection portion, and an internal circuit electrically connected to the electrode pad; and a second layer through which the second connection portion 32 passes. The first layer is elastically deformed such that the first connection portion, which has received a pressing force from the probe, comes into contact with the electrode pad.

### BRIEF DESCRIPTION OF THE DRAWINGS

FIG. 1 is a schematic view showing a configuration of an electrical connection apparatus according to an embodiment.

FIG. 2A is a schematic plan view showing the configuration of the electrical connection apparatus according to the embodiment.

FIG. 2B is a schematic cross-sectional view showing the configuration of the electrical connection apparatus according to the embodiment.

FIG. 3 is a schematic view showing the elastic deformation of a first layer of a wiring sheet in the electrical connection apparatus according to the embodiment.

FIG. 4 is a schematic view showing an original shape of the first layer of the wiring sheet in the electrical connection apparatus according to the embodiment.

FIG. 5 is a schematic view showing the elastic deformation of a second layer of the wiring sheet in the electrical connection apparatus according to the embodiment.

FIG. 6 is a schematic view showing an original shape of the second layer of the wiring sheet in the electrical connection apparatus according to the embodiment.

FIG. 7 is a schematic view showing the shape of a first space formed in the first layer of the wiring sheet in the electrical connection apparatus according to the embodiment.

FIG. 8 is a schematic view showing the shape of a second space formed in the second layer of the wiring sheet in the electrical connection apparatus according to the embodiment.

FIG. 9 is a schematic cross-sectional view showing a configuration example of a wiring layer of the wiring sheet in the electrical connection apparatus according to the embodiment.

FIG. 10 is a schematic view showing an example of an internal circuit of the wiring sheet in the electrical connection apparatus according to the embodiment.

FIG. 11 is a schematic view showing another example of an internal circuit of the wiring sheet in the electrical connection apparatus according to the embodiment.

FIG. 12 is a schematic view showing another example of an internal circuit of the wiring sheet in the electrical connection apparatus according to the embodiment.

FIG. 13 is a schematic view showing an example of a loopback circuit using the wiring sheet shown in FIG. 12.

FIG. 14 is a schematic view showing another example of an internal circuit of the wiring sheet in the electrical connection apparatus according to the embodiment.

FIG. 15 is a schematic view showing another example of an internal circuit of the wiring sheet in the electrical connection apparatus according to the embodiment.

FIG. 16 is a schematic view showing an example of an arrangement of electronic circuits on the wiring sheet in the electrical connection apparatus according to the embodiment.

### DETAILED DESCRIPTION

An embodiment will be described with reference to the drawings. In the description of the drawings below, the same or similar parts are denoted with the same or similar reference numerals. However, it should be noted that the drawings are schematically shown and the ratios of the thickness of each portion and the like are different from those in reality. Further, it is needless to say that the drawings include portions where the relationships and ratios of dimensions are different between drawings. The following embodiment exemplifies an apparatus and a method for embodying the technical concept of the present invention, and the embodiment does not specify the material, shape, structure, arrangement, and the like of components to the following.

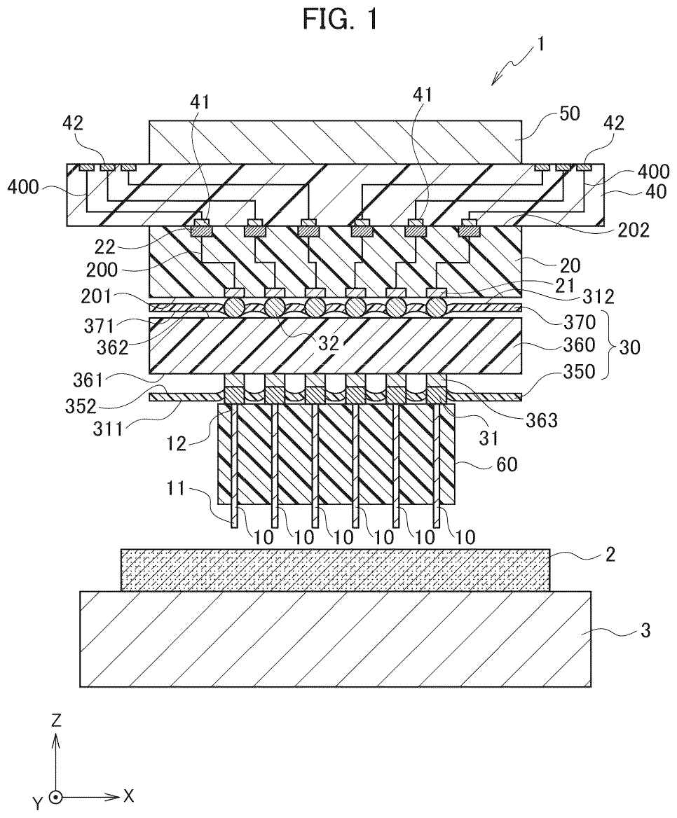

An electrical connection apparatus 1 according to an embodiment shown in FIG. 1 is used for inspecting an object 2 to be inspected. The electrical connection apparatus 1 includes probes 10, a probe head 60 holding the probes 10, a wiring sheet 30 laminated on the probe head 60, and a wiring board 20 laminated on the wiring sheet 30.

The electrical connection apparatus 1 further includes a printed board 40 laminated on the wiring board 20 and a stiffener 50 laminated on the printed board 40. In the following description, a direction in which the electrical connection apparatus 1 is located when viewed from the object 2 to be inspected is defined as an upward direction, and a direction in which the object 2 to be inspected is located when viewed from the electrical connection apparatus 1 is defined as a downward direction. As shown in FIG. 1, a direction from the downward direction to the upward direction is defined as a Z direction, and a plane perpendicular to the Z direction is defined as an XY plane. In FIG. 1, a left-right direction of the drawing is defined as an X direction, and a front-back direction is defined as a Y direction. Further, a surface facing the upward direction of each component of the electrical connection apparatus 1 will be referred to as an upper surface, and a surface facing the downward direction will be referred to as a lower surface.

Each probe 10 has a tip 11 which is one end arranged so as to be in contact with the object 2 to be inspected and a proximal end 12 which is the other end connected to the tip 11. The probes 10 are held while passing through through-holes formed in the probe head 60, for example. Each tip 11 and each proximal end 12 are exposed from the probe head 60.

The object 2 to be inspected is mounted on a stage 3. The electrical connection apparatus 1 and the stage 3 are movable relative to one another in an up-down direction. When the object 2 to be inspected is inspected, a distance between the electrical connection apparatus 1 and the stage 3 is made small, and tips 11 of the probes 10 contact signal terminals (not shown) of the object 2 to be inspected. FIG. 1 shows a state in which the probes 10 and the object 2 to be inspected are separated.

The wiring sheet 30 includes first connection portions 31 arranged on a first sheet surface 311 facing the probe head 60, and second connection portions 32 arranged on a second sheet surface 312 facing in an opposite direction of the first sheet surface 311. The wiring sheet 30 has an internal circuit (not shown in FIG. 1) electrically connected to at least any of the first connection portions 31 and the second connection portions 32. Each first connection portion 31 is connected to a proximal end 12 of each probe 10 which faces the first sheet surface 311 and which is exposed from the probe head 60. The wiring sheet 30 has flexibility and elastically deforms in a thickness direction. Details of the configuration of the wiring sheet 30 will be described later.

The wiring board 20 is arranged facing the probe head 60 with the wiring sheet 30 therebetween. First electrodes 21 electrically connected to the second connection portions 32 of the wiring sheet 30 are arranged on a first main surface 201 of the wiring board 20 facing the second sheet surface 312 of the wiring sheet 30. Second electrodes 22 are arranged on a second main surface 202 of the wiring board 20 which faces the printed board 40 and faces in an opposite direction of the first main surface 201. The first electrodes 21 and the second electrodes 22 are electrically connected via internal wiring 200. A multilayer wiring board such as a Multi-Layer Organic (MLO) board or a Multi-Layer Ceramic (MLC) board may be used for the wiring board 20, for example.

The printed board 40 is arranged facing the second main surface 202 of the wiring board 20. The printed board 40 has first ends 41 arranged on a lower surface thereof facing the wiring board 20, second ends 42 arranged on an upper surface thereof, and wiring patterns 400 for electrically connecting the first ends 41 and the second ends 42. The second ends 42 are electrically connected to an inspection device (not shown), for example. As a result, an electrical signal propagates between the object 2 to be inspected and the inspection device via the electrical connection apparatus 1.

The wiring board 20 may be a space transformer that transforms a distance between the proximal ends 12 of the probes 10 to a distance between the first ends 41 of the printed board 40, when viewed from a direction normal to the second main surface 202 of the wiring board 20, for example. Due to the wiring board 20 being the space transformer, it is possible to electrically connect the signal terminals arranged on the object 2 to be inspected to the second ends 42 of the printed board 40 which are arranged at a distance larger than a distance between the signal terminals. This facilitates the electrical connection between the wiring patterns 400 in the printed board 40 and the inspection device.

As shown in FIG. 1, the stiffener 50 may be laminated on the printed board 40. The stiffener 50 has higher stiffness than the printed board 40, and ensures the mechanical strength of the electrical connection apparatus 1 by preventing the printed board 40 from being bent. In addition, the stiffener 50 may be used as a support for fixing each component of the electrical connection apparatus 1. The stiffener 50 may be fixed to the printed board 40 using screws, for example.

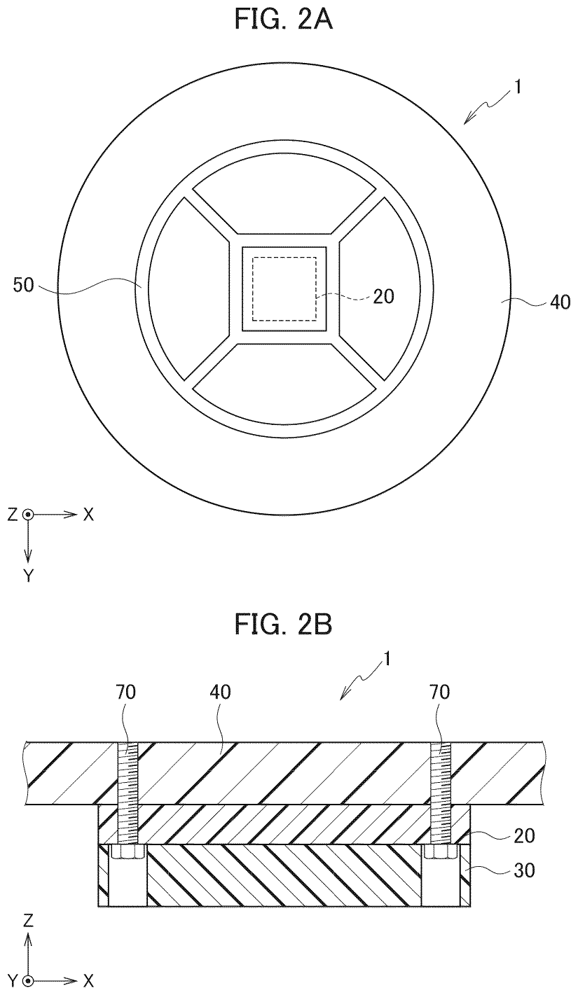

FIG. 2A is a plan view (hereinafter also referred to as “in plan view”) of a structure in which the wiring board 20, the printed board 40, and the stiffener 50 are laminated, as viewed from the Z direction. FIG. 2B is a cross-sectional view of a side surface as viewed from the Y direction of an XY plane perpendicular to the Z direction. FIG. 2B does not show the first electrodes 21 and the second electrodes 22 of the wiring board 20, the first connection portions 31 and the second connection portions 32 of the wiring sheet 30, and the wiring patterns 400 in the printed board 40.

The stiffener 50 is arranged on an upper surface of the printed board 40 that is circular in plan view. As shown in FIG. 2A, the stiffener 50 has a shape in which an outer circular ring and an inner rectangular ring are connected using spokes, for example. The wiring board 20 and the wiring sheet 30 are arranged in the vicinity of the center of a lower surface of the printed board 40. The wiring board 20, the printed board 40, and the stiffener 50 are fixed with screws, for example. FIG. 2B shows an example in which the wiring board 20 and the printed board 40 are joined using screws 70. The wiring sheet 30 is not screwed, and is interposed and held between the probe head 60 and the wiring board 20. The wiring sheet 30 has holes for inserting the screws 70.

Details of a configuration of the wiring sheet 30 will be described below. As shown in FIG. 1, the wiring sheet 30 includes a first layer 350, a wiring layer 360, and a second layer 370. The first layer 350, the wiring layer 360, and the second layer 370 are arranged in this order in a thickness direction of the wiring sheet 30 (Z direction).

Both surfaces of the first layer 350 are defined by the first sheet surface 311 and a first facing surface 352. The first connection portions 31 pass through the first layer 350 from the first sheet surface 311 to the first facing surface 352.

Both surfaces of the wiring layer 360 are defined by a first connection surface 361 facing the first facing surface 352 and a second connection surface 362 facing in an opposite direction of the first connection surface 361. The wiring layer 360 includes electrode pads 363 arranged on the first connection surface 361 separated from the first layer 350 so as to face the first connection portions 31, and an internal circuit (not shown) electrically connected to the electrode pads 363.

Both surfaces of the second layer 370 are defined by a second facing surface 371 facing the second connection surface 362 and the second sheet surface 312. The second connection portions 32 pass through the second layer 370 from the second facing surface 371 to the second sheet surface 312.

The peripheries of the first connection portions 31 of the first layer 350 are elastically deformed such that the first connection portions 31, which have received pressing forces from the proximal ends 12 of the probes 10, contact the electrode pads 363.

The second layer 370 is separated from the second connection surface 362 in the peripheries of the second connection portions 32. The peripheries of the second connection portions 32 of the second layer 370 are elastically deformed such that the second connection portions 32 are energized toward the first electrodes 21.

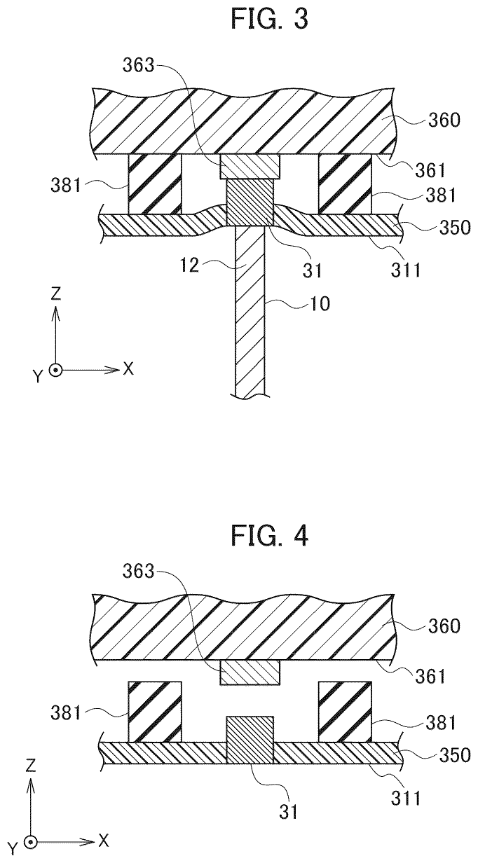

When the electrical connection apparatus 1 is assembled, a pressing force is applied to press the first connection portions 31 against the proximal ends 12 of the probes 10. Pressing the first connection portions 31 against the proximal ends 12 will be hereinafter referred to as “preloading”. The probe head 60 holding the probes 10 is attached to the wiring sheet 30. Then, the first layer 350 is elastically deformed such that each first connection portion 31 contacts each electrode pad 363 as shown in FIG. 3. In other words, the first layer 350 is elastically deformed during preloading. The first connection portions 31 of the wiring sheet 30 are pressed against the probes 10 by an elastic force of the first layer 350. As a result, the probes 10 and the first connection portions 31 are in stable contact.

When the probes 10 are separated from the wiring sheet 30, a shape of the first layer 350 is returns to an original shape such that each first connection portion 31 is away from each electrode pad 363 as shown in FIG. 4. In other words, FIG. 4 shows a state of the wiring sheet 30 before the probe head 60 is attached to the wiring sheet 30.

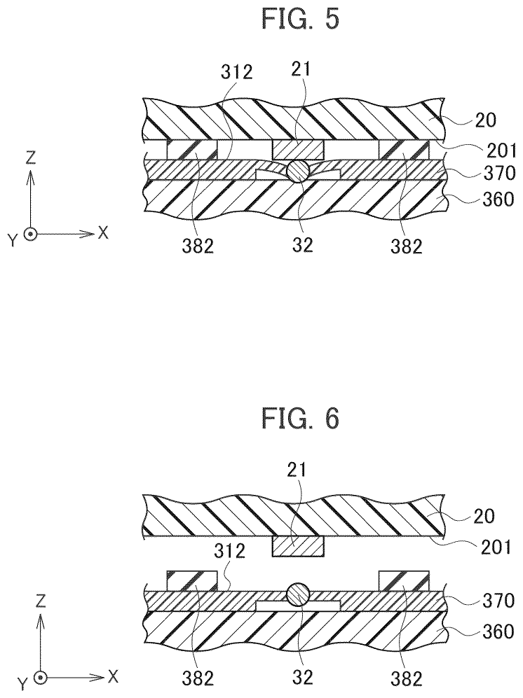

The peripheries of the second connection portions 32 of the second layer 370 are formed to be elastically deformable. Therefore, when the wiring board 20 is attached to the wiring sheet 30, each second connection portion 32 of the wiring sheet 30 energized against each first electrode 21 of the wiring board 20 is pressed against the wiring layer 360 as shown in FIG. 5. Each second connection portion 32 and each first electrode 21 are reliably contacted by an elastic force of the elastically deformed second layer 370. A gold ball or the like may be used for each second connection portion 32, for example.

When the wiring board 20 is separated from the wiring sheet 30, a shape of the periphery of each second connection portion 32 of the second layer 370 returns to an original shape as shown in FIG. 6. In other words, FIG. 6 shows a state of the wiring sheet 30 before the wiring sheet 30 is attached to the wiring board 20.

As shown in FIGS. 3 and 4, first spacers 381 are arranged in regions in the periphery of a region where each first connection portion 31 is arranged, between the first layer 350 and the wiring layer 360 of the wiring sheet 30. A space is formed between the first layer 350 and the wiring layer 360 by the first spacers 381. Due to the first spacers 381 being arranged in the periphery of each first connection portion 31, the first layer 350 is curved in the space range between the first layer 350 and the wiring layer 360. In other words, the degree of curvature of the first layer 350 is limited by the thickness of each first spacer 381 in the Z direction.

As shown in FIGS. 5 and 6, second spacers 382 are arranged in regions in the periphery of a region where each second connection portion 32 is arranged, between the second layer 370 of the wiring sheet 30 and the wiring board 20. A space is formed between the second layer 370 and the wiring board 20 by the second spacers 382. Due to the second spacers 382 being arranged in the periphery of each second connection portion 32, the second layer 370 is curved in the space range between the second layer 370 and the wiring board 20. In other words, the degree of curvature of the second layer 370 is limited by the thickness of each second spacer 382 in the Z direction.

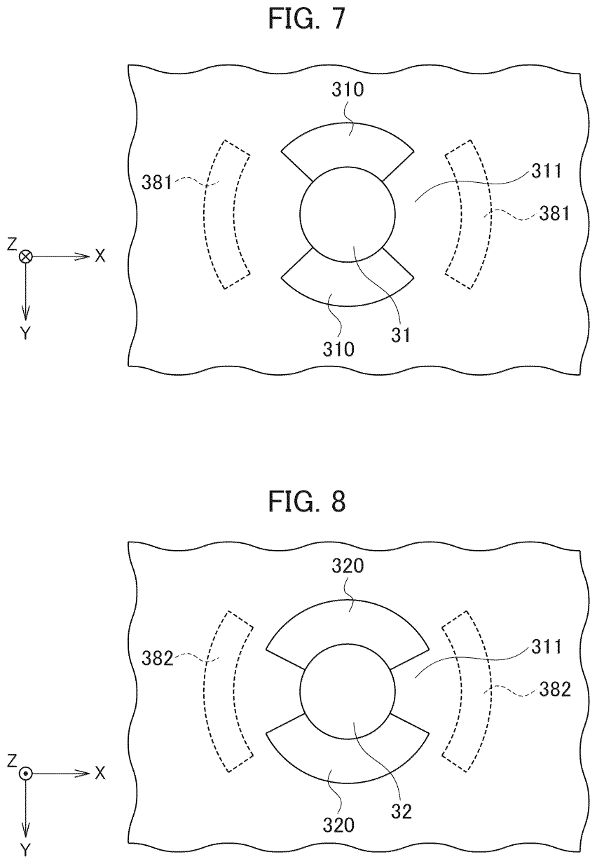

In order to elastically deform the periphery of each first connection portion 31 of the first layer 350, first spaces 310 for bending may be disposed in the periphery of each first connection portion 31 in the first layer 350 as shown in FIG. 7, for example. The periphery of each first connection portion 31 can be elastically deformed by arranging each first connection portion 31 in a region with flexibility and with the first spaces 310 disposed in the periphery thereof. The magnitude of an elastic force can be adjusted by setting the area size of each first space 310.

In order to elastically deform the periphery of each second connection portion 32 of the second layer 370, second spaces 320 for bending may be disposed in the periphery of each second connection portion 32 in the second layer 370 as shown in FIG. 8, for example. The periphery of each second connection portion 32 can be elastically deformed by arranging each second connection portion 32 in a region with flexibility and with the second spaces 320 disposed in the periphery thereof. The magnitude of an elastic force can be adjusted by setting the area size of each second space 320. The area of each first space 310 and the area of each second space 320 may be different. If an elastic force of the second layer 370 may be smaller than that of the first layer 350, the area of each second space 320 may be larger than that of each first space 310, for example.

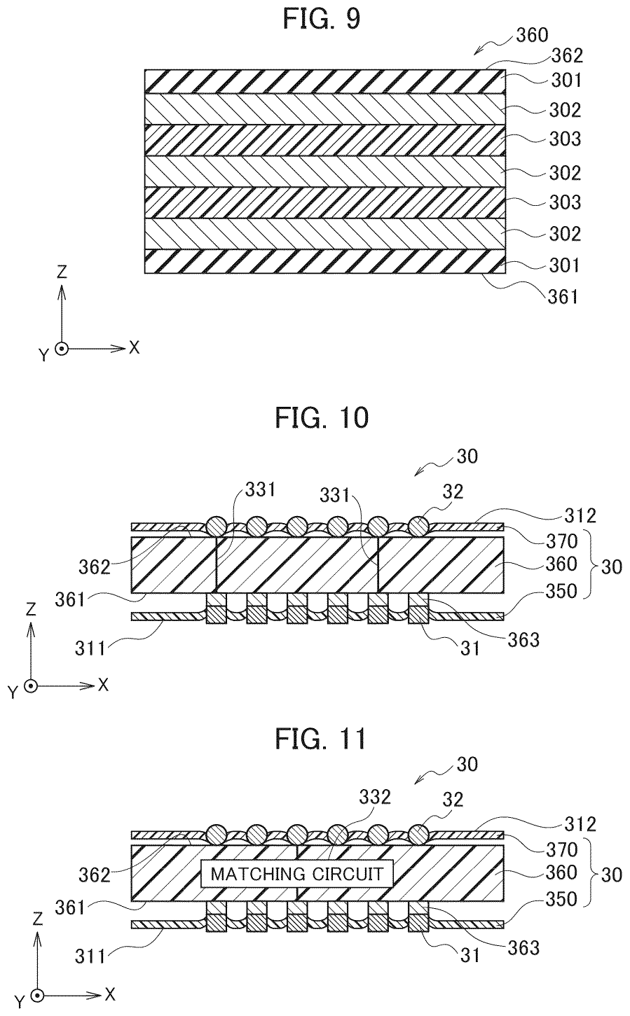

Insulating films may be used for the first layer 350 and the second layer 370 of the wiring sheet 30, for example. The wiring layer 360 may have a structure in which a conductive film and an insulating film are laminated. An internal circuit may be constituted from a conductive pattern formed on a conductive film, for example. FIG. 9 shows an example of a configuration of the wiring layer 360 of the wiring sheet 30. FIG. 9 does not show the electrode pads 363 and the like.

The wiring layer 360 of the wiring sheet 30 shown in FIG. 9 has a structure in which a laminated body constituted by conductive films 302 and insulating films 303 is interposed between a pair of cover films 301 of insulating materials. The number of laminated bodies constituted by the conductive films 302 and the insulating films 303 can be set to any number. The conductive films 302 may be metal materials such as copper foils, for example. The insulating films 303 may be insulating materials such as polyimide sheets, for example. The cover films 301 may be insulating materials such as solder resists, for example. An adhesive may be used for joining the conductive films 302, the insulating films 303, and the cover films 301 each other, for example. The wiring layer 360 may have a structure in which a film (also referred to as a “base film”) of an insulating material is further interposed between laminated bodies including the conductive films 302 and the insulating films 303. The cover films 301 may be used for the first layer 350 and the second layer 370.

The wiring sheet 30 may be selected from among a plurality of wiring sheet candidates. Each of the wiring sheet candidates has a first connection portion 31 arranged on the first sheet surface 311, a second connection portion 32 arranged on the second sheet surface 312, and a wiring layer 360 on which an internal circuit is formed. Each of the wiring sheet candidates may include an internal circuit having a configuration different from that of another wiring sheet candidate. One wiring sheet 30 selected from among the plurality of wiring sheet candidates may be configured in an attachable/detachable manner between the probe head 60 and the wiring board 20.

An example of the configuration of wiring sheet candidates included in a wiring sheet group will be described below. In the following, when each of the wiring sheet candidates is not limited, the wiring sheet candidates will be collectively referred to as a wiring sheet 30.

An internal circuit of a wiring sheet 30 as any one of the group of wiring sheets may include a circuit for electrically connecting the first connection portions 31 and the second connection portions 32 (hereinafter also referred to as an “interposer circuit”). When the interposer circuit is formed on the wiring layer 360 having the structure shown in FIG. 9, wiring is formed, which passes through the cover films 301, the conductive films 302, and the insulating films 303, from the first connection surface 361 to the second connection surface 362 of the wiring layer 360, for example.

If the internal circuit of the wiring sheet 30 includes the interposer circuit, the internal circuit of the wiring sheet 30 shown in FIG. 10 may include a circuit for short-circuiting the first connection portions 31 and the second connection portions 32. In the internal circuit of the wiring sheet 30 shown in FIG. 10, the first connection portions 31 and the second connection portions 32 are electrically short-circuited by short-circuit wiring 331.

By attaching the wiring sheet 30 shown in FIG. 10 to the electrical connection apparatus 1, the probes 10 and the wiring patterns 400 in the printed board 40 are short-circuited via the internal circuit of the wiring sheet 30. This electrically connects the object 2 to be inspected and the inspection device. As a result, an electrical signal propagates between an inspection device such as an IC tester and the object 2 to be inspected, and characteristics of the object 2 to be inspected are measured. One first connection portion 31 and one second connection portion 32 are connected in a one-to-one relationship by means of the internal circuit of the wiring sheet 30, for example. Alternatively, one first connection portion 31 may be connected to a plurality of second connection portions 32, or a plurality of first connection portions 31 may be connected to one second connection portion 32 by means of the internal circuit.

When the internal circuit of the wiring sheet 30 includes the interposer circuit, the internal circuit may include a matching circuit 332 having a first terminal connected to a first connection portion 31 and a second terminal connected to a second connection portion 32 as shown in FIG. 11. The matching circuit 332 may perform impedance matching between the first connection portion 31 and the second connection portion 32. The matching circuit 332 may include a x-type filter, for example.

The internal circuit of the wiring sheet 30 may include a circuit for electrically connecting any one of the first connection portions 31 and another one of the first connection portions 31. In other words, the internal circuit of the wiring sheet 30 may include a circuit for electrically connecting an output terminal and an input terminal of the object 2 to be inspected (hereinafter also referred to as a “loopback circuit”). Two signal terminals of the object 2 to be inspected are electrically connected by the loopback circuit.

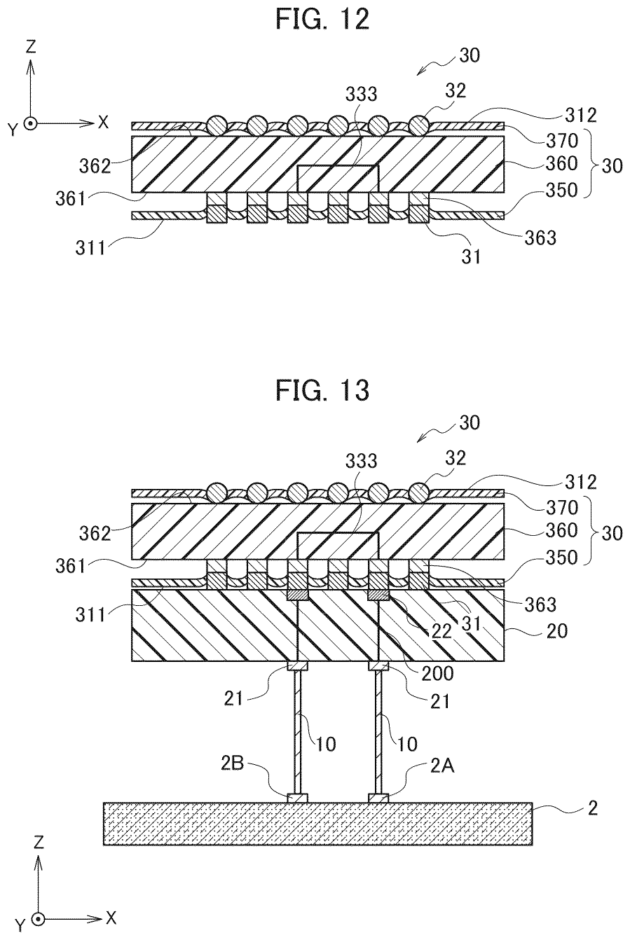

The internal circuit of the wiring sheet 30 may include a circuit for short-circuiting any one of the first connection portions 31 and another one of the first connection portions 31 as shown in FIG. 12, for example. In the internal circuit of the wiring sheet 30 shown in FIG. 12, the one first connection portion 31 and the other first connection portion 31 are electrically short-circuited by loopback wiring 333. By attaching the wiring sheet 30 shown in FIG. 12 to the electrical connection apparatus 1, one of the probes 10 and another one of the probes 10 are short-circuited via the internal circuit of the wiring sheet 30. This electrically connects one signal terminal and the other signal terminal of the object 2 to be inspected.

FIG. 13 shows a configuration in which a first signal terminal 2A of the object 2 to be inspected in contact with one of the probes 10, and a second signal terminal 2B of the object 2 to be inspected in contact with another one of the probes 10 are electrically connected via the loopback wiring 333 of the wiring sheet 30. Suppose that the object 2 to be inspected is a receiving circuit, the first signal terminal 2A is an output terminal of the object 2 to be inspected, and the second signal terminal 2B is an input terminal of the object 2 to be inspected, for example. In the above case, a transmission test can be performed by returning an output from the object 2 to be inspected to an input. In other words, it is possible to test whether an output portion and an input portion of the object 2 to be inspected are functioning normally, even if there is no destination equipment for transmission. As an inspection in accordance with a jitter tolerance test performed for the receiving circuit, an output signal output from the first signal terminal 2A (output terminal) may be input to the second signal terminal 2B (input terminal) as an input signal to inspect whether a specified error rate is ensured, for example.

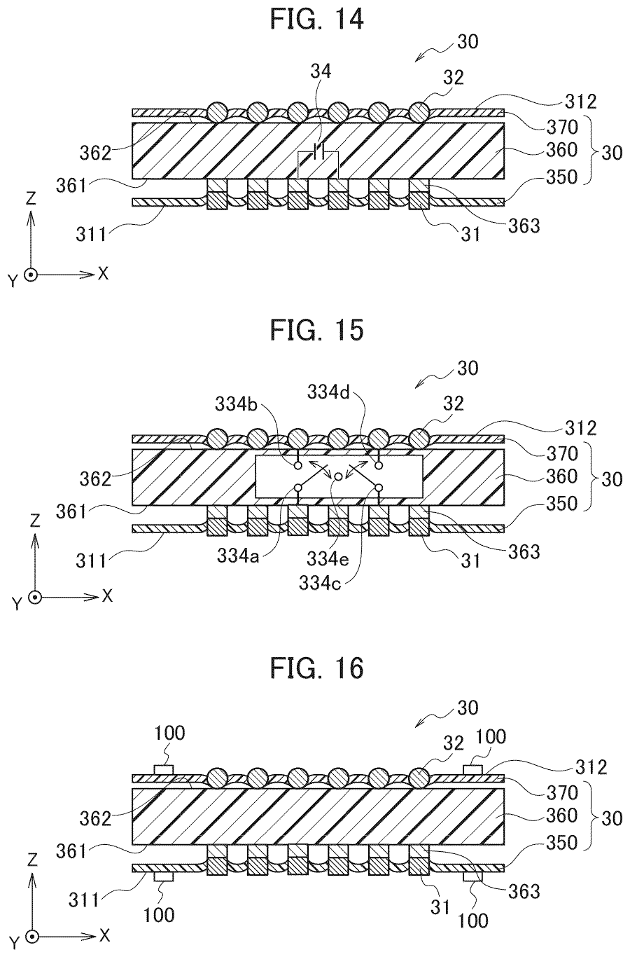

When the internal circuit of the wiring sheet 30 includes the loopback circuit, the internal circuit may include a circuit having a capacitor 34 connected in series between any one of the first connection portions 31 and another one of the first connection portions 31 as shown in FIG. 14. One terminal of the capacitor 34 is connected to the one first connection portion 31, and the other terminal of the capacitor 34 is connected to the other first connection portion 31. The capacitor 34 may be a capacitor formed using a semiconductor manufacturing process (hereinafter also referred to as a “process capacitor”).

Further, the internal circuit of the wiring sheet 30 may include a relay circuit that switches to electrically connect one of the first connection portions 31 to either one of the second connection portions 32 or another one of the first connection portions 31. The internal circuit shown in FIG. 15 includes a relay circuit 334 that constitutes either the interposer circuit for connecting the first connection portions 31 and the second connection portion 32 or the loopback circuit for connecting the first connection portions 31 each other, for example.

When the relay circuit 334 shown in FIG. 15 constitutes the interposer circuit, a first contact terminal 334a and a second contact terminal 334b are connected, and a third contact terminal 334c and a fourth contact terminal 334d are connected. This electrically connects the first connection portions 31 and the second connection portions 32. When the relay circuit 334 constitutes the loopback circuit, the first contact terminal 334a and a common contact terminal 334e of the relay circuit 334 are connected, and the third contact terminal 334c and the common contact terminal 334e are connected. This electrically connects one of the first connection portions 31 and another one of the first connection portions 31.

Although examples of the internal circuit of the wiring sheet 30 have been described with reference to FIGS. 10 to 15, it is needless to say that the configuration of the internal circuit is not limited to the above. The internal circuit may include an inductor instead of the capacitor 34 shown in FIG. 14, or the internal circuit may include both a capacitor and an inductor, for example. In other words, the internal circuit of the wiring sheet 30 may include a passive circuit including any element. Further, the internal circuit may include a switching circuit using a diode or the like instead of the relay circuit 334 shown in FIG. 15.

An element included in the internal circuit of the wiring sheet 30 may be formed using a Micro Electro Mechanical Systems (MEMS) process, for example. By using the MEMS process, an element which is reduced in size can be formed integrally with the wiring sheet 30.

As described above, various circuit configurations as shown in FIGS. 10 to 15 can be implemented in the electrical connection apparatus 1 by merely replacing the wiring sheet 30 in the electrical connection apparatus 1, for example. Therefore, a plurality of types of measurements can be performed on the object 2 to be inspected using the electrical connection apparatus 1. A DC test may be performed on the object 2 to be inspected by mounting, in the electrical connection apparatus 1, the wiring sheet 30 including the internal circuit for short-circuiting the first connection portions 31 and the second connection portions 32, for example. Further, a high-frequency test may be performed on the object 2 to be inspected by mounting, in the electrical connection apparatus 1, the wiring sheet 30 including the internal circuit having the matching circuit or the loopback circuit.

Further, by arranging the relay circuit 334 in the wiring sheet 30 shown in FIG. 15 of the electrical connection apparatus 1, the wiring length of the interposer circuit and the loopback circuit can be reduced, compared to that when a relay element is arranged on the printed board 40. As a result, according to the electrical connection apparatus 1, it is possible to shorten a propagation path of an electrical signal and suppress the loss of an electrical signal and noise.

Further, by arranging the matching circuit 332 in the wiring sheet 30 of the electrical connection apparatus 1 as shown in FIG. 11, wiring connected to the matching circuit 332 can be shortened. The matching circuit 332 can be arranged in the immediate vicinity of wiring for which impedance matching is to be performed, and therefore impedance matching can be performed effectively, for example.

As described above, the electrical connection apparatus 1 has the wiring sheet 30 including the internal circuit capable of constituting any circuit, which is interposed between the wiring board 20 and the printed board 40 in an attachable/detachable manner, and therefore it is possible to configure an arbitrary measurement system. As a result, characteristics of the object 2 to be inspected can be measured with high accuracy with the electrical connection apparatus 1.

Further, the wiring sheet 30 with flexibility which is interposed between the probe head 60 and the wiring board 20 in the electrical connection apparatus 1 can mitigate warpages and irregularities of surfaces of the probe head 60 and the wiring board 20. This can suppress the rattling and contact failure of the electrical connection apparatus caused by a gap between the probe head 60 and the wiring board 20.

Further, electronic components electrically connected to the internal circuit can be arranged on a surface of the wiring sheet 30 in the electrical connection apparatus 1. As shown in FIG. 16, electronic components 100 connected to the internal circuit of the wiring sheet 30 may be arranged on both of the first sheet surface 311 and the second sheet surface 312, for example. Each electronic component 100 may be a capacitor, an inductor, or a resistance element, for example. FIG. 16 shows an example of arranging the electronic components 100 on both of the first sheet surface 311 and the second sheet surface 312, but the electronic components 100 may be arranged on either the first sheet surface 311 or the second sheet surface 312. By arranging the electronic components 100 on a surface of the wiring sheet 30, it is possible to reduce or divide the number of electronic components arranged on the wiring board 20 or the printed board 40, for example. Further, by arranging electronic components on the surface of the wiring sheet 30, it is possible to reduce the wiring length between the object 2 to be inspected and each electronic component. Therefore, by arranging electronic components such as capacitors for reducing power source noise on the wiring sheet 30, it is possible to stably perform measurements on the object 2 to be inspected, for example.

As described above, during preloading in an assembly process of the electrical connection apparatus 1, after the proximal ends 12 of the probes 10 and the first connection portions 31 of the first layer 350 of the wiring sheet 30 come into contact with each other, the first layer 350 is pushed toward the wiring layer 360 by the probes 10. The first layer 350 is curved, and the degree of curvature is limited by the thickness of each first spacer 381. Then, the first connection portions 31 come into contact with the electrode pads 363. The proximal ends 12 of the probes 10 are electrically connected to the internal wiring 200 in the wiring board 20 via the internal circuit of the wiring sheet 30.

Therefore, according to the electrical connection apparatus 1, the curvature of the first layer 350 mitigates a part of a load applied until the first connection portions 31 of the first layer 350 come into contact with the electrode pads 363 of the wiring layer 360. This can reduce the load applied to the probes 10 during preloading. As a result, breakage of the probes 10 can be prevented.

Meanwhile, all loads due to preloading are applied to probes 10 of an electrical connection apparatus of a comparative example not including the wiring sheet 30. Therefore, it is necessary to reduce the loads applied to the probes 10 of the electrical connection apparatus of the comparative example, compared with those in the electrical connection apparatus 1.

As described above, according to the electrical connection apparatus 1, the load applied to the probes 10 can be reduced. This can increase the maximum load applied to the probes 10 when the object 2 to be inspected is inspected. Therefore, it is possible to prevent breakage of the probes 10 caused by bringing the electrical connection apparatus 1 close to the object 2 to be inspected in order to ensure the electrical connection between the probes 10 and the object 2 to be inspected. When positions of the tips 11 of the probes 10 vary, the electrical connection apparatus 1 can be brought close to the object 2 to be inspected such that a probe 10 having a long distance from the object 2 to be inspected reliably contacts the object 2 to be inspected, for example. At this time, the breakage of a probe 10 having a short distance from the object 2 to be inspected can be prevented due to the maximum load applied to the probes 10 being large.

The limit of the load applied to the probes 10 increases according to the length of the probes 10. Therefore, according to the electrical connection apparatus 1 which enables reduction of the load applied to the probes 10, the length of the probes 10 of the electrical connection apparatus 1 can be reduced compared to that of probes of the electrical connection apparatus of the comparative example. By reducing the length of the probes 10, signal wiring in the electrical connection apparatus 1 can be shortened. Therefore, according to the electrical connection apparatus 1, it is possible to enhance the accuracy of high-frequency current characteristics of the object 2 to be inspected.

### OTHER EMBODIMENTS

Although an embodiment of the present invention has been described above, the discussion and drawings forming part of this disclosure should not be construed as limiting the invention. Various alternative embodiments, examples, and operational techniques will be apparent to those skilled in the art from this disclosure.

The wiring sheet 30 may include an internal circuit in which a plurality of types of circuit configurations are mixed, for example. The wiring sheet 30 may include an internal circuit in which the short-circuit wiring 331 and the matching circuit 332 are mixed, for example. Alternatively, the wiring sheet 30 may include an internal circuit in which an interposer circuit and a loopback circuit are mixed. The internal circuit may include the short-circuit wiring 331, the matching circuit 332, and the loopback wiring 333, or may further include the relay circuit 334, for example. Further, the loopback circuit may include the matching circuit 332. In this way, any circuit can be configured in the internal circuit of the wiring sheet 30.

As described above, by mounting, in the electrical connection apparatus 1, the wiring sheet 30 including the internal circuit in which any circuit configurations are mixed, a plurality of types of measurements can be performed on the object 2 to be inspected with one wiring sheet 30.

In this way, it is needless to say that the present invention includes various embodiments not described above. Therefore, the technical scope of the present invention is defined only by matters specified in the invention that are within the scope of claims appropriate from the above description.

### REFERENCE SIGNS LIST

1 Electrical connection apparatus
2 Object to be inspected
10 Probe
11 Tip
12 Proximal end
20 Wiring board
21 First electrode
22 Second electrode
30 Wiring sheet
31 First connection portion
32 Second connection portion
40 Printed board
41 First end
42 Second end
50 Stiffener
60 Probe head
100 Electronic component
200 Internal wiring
201 First main surface
202 Second main surface
311 First sheet surface
312 Second sheet surface
350 First layer
352 First facing surface
360 Wiring layer
361 First connection surface
362 Second connection surface
363 Electrode pad
370 Second layer
371 Second facing surface
381 First spacer
382 Second spacer
400 Wiring pattern

What is claimed is:

1. An electrical connection apparatus used for inspecting an object to be inspected, the electrical connection apparatus comprising:
a probe having a tip arranged so as to be in contact with the object to be inspected and a proximal end connected to the tip;
a probe head holding the probe;
a wiring sheet with flexibility including a first connection portion arranged on a first sheet surface facing the probe head and a second connection portion arranged on a second sheet surface facing in an opposite direction of the first sheet surface; and
a wiring board which is arranged facing the probe head with the wiring sheet therebetween and has a first main surface on which a first electrode facing the second connection portion is arranged, wherein
the wiring sheet includes:
a first layer which has both surfaces defined by the first sheet surface and a first facing surface and through which the first connection portion passes from the first sheet surface to the first facing surface;
a wiring layer which has both surfaces defined by a first connection surface facing the first facing surface and a second connection surface facing in an opposite direction of the first connection surface, and which includes an electrode pad arranged on the first connection surface separated from the first layer so as to face the first connection portion, and an internal circuit electrically connected to the electrode pad; and
a second layer which has both surfaces defined by a second facing surface facing the second connection surface and the second sheet surface and through which the second connection portion passes from the second facing surface to the second sheet surface, and
the first layer is elastically deformed such that the first connection portion, which has received a pressing force from the proximal end, comes into contact with the electrode pad.

2. The electrical connection apparatus according to claim 1, wherein
the second layer is separated from the second connection surface at the periphery of the second connection portion, and
the periphery of the second connection portion of the second layer is elastically deformed such that the second connection portion is energized toward the first electrode.

3. The electrical connection apparatus according to claim 1, wherein
a first spacer constituting a space formed between the first layer and the wiring layer is arranged in the periphery of the first connection portion, between the first layer and the wiring layer.

4. The electrical connection apparatus according to claim 1, wherein
a second spacer constituting a space formed between the second layer and the wiring board is arranged in the periphery of the second connection portion, between the second layer and the wiring board.

5. The electrical connection apparatus according to claim 1, wherein
the wiring sheet has a structure in which a laminated body constituted by a conductive film and an insulating film is interposed between cover films of an insulating material.

6. The electrical connection apparatus according to claim 1, further comprising:
a printed board that is arrange facing the wiring board and has a wiring pattern connected to a second electrode arranged on a second main surface facing in an opposite direction of the first main surface of the wiring board.

7. The electrical connection apparatus according to claim 6, wherein
the probe is provided in plurality, the wiring pattern is provided in plurality, and the wiring board is a space transformer which transforms a distance between the probes into a distance between the wiring patterns of the printed board, when viewed from a direction normal to the main surface of the wiring board.
